(19) United States
(12) Patent Application Publication
(10) Pub. No.: US 2023/0370053 A1
(43) Pub. Date: Nov. 16, 2023

(54) HIGH VOLTAGE WAVEFORM GENERATOR WITH ANALOG SWITCHING ARRAY

(71) Applicant: Artimus Robotics Inc., Boulder, CO (US)

(72) Inventor: Shane Karl MITCHELL, Boulder, CO (US)

(73) Assignee: Artimus Robotics Inc., Boulder, CO (US)

(21) Appl. No.: 18/196,923

(22) Filed: May 12, 2023

Related U.S. Application Data
(60) Provisional application No. 63/341,477, filed on May 13, 2022.

(51) Int. Cl. H03K 3/57; H03K 7/08; H03K 3/42

(52) U.S. Cl. CPC H03K 3/57; H03K 7/08; H03K 3/42

(57) ABSTRACT

A high-voltage (HV) waveform generator for driving an electrostatic actuator includes an HV source configured to generate a single HV rail at a predefined voltage with respect to a low potential, at least one switch circuit, and a controller. Each at least one switching circuit includes a first charge sub-circuit, a first discharge sub-circuit, a second charge sub-circuit, and a second discharge sub-circuit in a H-bridge formation to provide a first voltage output and a second voltage output. The controller includes software that generates variable current sources to control the first charge sub-circuit, the first discharge sub-circuit, the second charge sub-circuit, and the second discharge sub-circuit input to generate desired voltages at the first voltage output and the second voltage output based on feedback from a first voltage monitors for the first voltage output and a second voltage monitor for the second voltage output.

### RELATED APPLICATION

This application claims priority to U.S. Patent Application Ser. No. 63/341,477, titled “High Voltage Waveform Generation Using Analog Switching Arrays”, filed May 13, 2022, which is incorporated herein by reference in its entirety.

### BACKGROUND

High voltage (HV) waveform generation is typically done at the amplifier level, which requires the amplifier to have a high slew rate to source and sink charge. Such amplifiers are typically expensive and bulky, and have limited dynamic range for independent control of multiple simultaneous outputs.

### SUMMARY

In certain embodiment, the techniques described herein relate to a high-voltage (HV) waveform generator, including: an HV source configured to generate a single HV rail at a predefined voltage with respect to a low potential; at least one switch circuit having: a first charge sub-circuit implementing a first switch to electrically couple the single HV rail and a first voltage output; a first discharge sub-circuit implementing a second switch to electrically couple the first voltage output and the low potential; a second charge sub-circuit implementing a third switch to electrically couple the single HV rail and a second voltage output; and a second discharge sub-circuit implementing a fourth switch to electrically couple the second voltage output and the low potential; and a controller having at least one digital processor and memory storing machine-readable instructions that, when executed by the digital processor, cause the digital processor to generate a first variable current source input to the first charge sub-circuit to control the first switch, a second variable current source input to the first discharge sub-circuit to control the second switch, a third variable current source input to the second charge sub-circuit to control the third switch, and a fourth variable current source input to the second discharge sub-circuit to control the fourth switch.

In certain embodiment, the techniques described herein relate to a high-voltage (HV) waveform generator, including: an HV source configured to generate a single HV rail at a predefined voltage with respect to a low potential; at least one switch circuit having: a charge sub-circuit implementing a first switch to electrically couple the single HV rail and a voltage output; a discharge sub-circuit implementing a second switch to electrically couple the voltage output and the low potential; and a controller having at least one digital processor and memory storing machine-readable instructions that, when executed by the digital processor, cause the digital processor to generate a first variable current source signal input to the charge sub-circuit to control the first switch, and a second variable current source to control the second switch.

### BRIEF DESCRIPTION OF THE FIGURES

FIG. 1 is a schematic diagram illustrating one example high-voltage (HV) waveform generator using an analog switching array, in embodiments.

FIG. 2 is a circuit diagram illustrating example detail of the switch circuit of FIG. 1, in embodiments.

FIG. 3 shows one example switch circuit with the second channel omitted, in embodiments.

FIG. 4 is a circuit diagram illustrating one example H-bridge configuration switch circuit with a current monitor in each channel, in embodiments.

FIG. 5A is a graph illustrating example operation of the HV waveform generator of FIG. 1 for conventional operation of a capacitive load.

FIG. 5B is a graph illustrating example operation of the HV waveform generator of FIG. 1 for improved operation of the capacitive load, in embodiments.

FIG. 6A is a graph showing a low frequency signal.

FIG. 6B is a graph showing a high frequency signal.

FIG. 6C is a graph showing an example output of the HV waveform generator of FIG. 1 that combines the low frequency signal of FIG. 6A with the high frequency signal of FIG. 6B.

FIG. 7 is a flowchart illustrating one example method for HV waveform generation, in embodiments.

FIG. 8 is a circuit diagram illustrating the switch circuit of FIG. 2 showing analog current sources representing the variable current sources, in embodiments.

FIG. 9 is a circuit diagram illustrating the switch circuit of FIG. 3 showing analog current sources representing the variable current sources, in embodiments.

### DETAILED DESCRIPTION OF THE EMBODIMENTS

Embodiments herein disclose a high-voltage (HV) waveform generator capable of driving a wide variety of resistive, capacitive, electrostatic, and inductive loads (hereinafter “load”) requiring a high voltage (e.g., up to 15 kV) and peak currents up to 10 mA. The HV waveform generator may drive a Hydraulically-Amplified Self-Healing Electrostatic (HASEL) actuator, which has direct electrical control and provides very fast response times that eliminate the need for a connection to compressed air, as used in conventional soft actuators. Embodiments of the HV waveform generator control the HASEL actuator to provide variable force or displacement based on an applied electrical control signal.

One aspect of the present embodiments includes the realization that conventional HV waveform generation is typically done at the amplifier level, which requires the amplifier to have a high slew rate to source and sink charge. Such amplifiers are typically expensive and bulky, and have limited dynamic range for independent control of multiple simultaneous outputs. The present embodiments solve this problem by shifting the dynamic responsibilities from the amplifier to at least one switching channel. Advantageously, only a single HV source is required (though multiple sources may be used if desired) as a voltage rail and may be set to a predefined DC voltage level. An arbitrary number of switching channels may connect to the single HV source, where each switching channel draws a charge from the single HV rail to generate a dynamic HV control signal to power at least one load (e.g., a HASEL actuator).

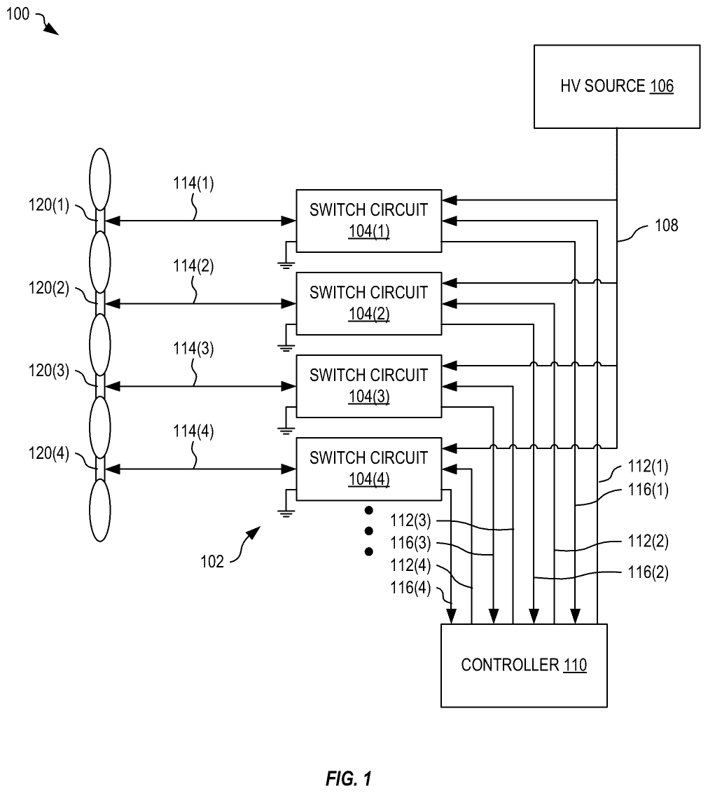

FIG. 1 is a schematic diagram illustrating one example high-voltage (HV) waveform generator 100 using an analog switching array 102, in embodiments. In this example, analog switching array 102 is shown with four switch circuits 104(1)-104(4) but may have more or fewer switches without departing from the scope hereof. HV waveform generator 100 includes an HV source 106 that generates a high voltage on a single HV rail 108 that electrically couples to each switch circuit 104.

HV waveform generator 100 may also include a controller 110 (e.g., having a digital processor, memory storing machine-readable instructions executable by the processor, inputs and outputs) that generates a control signal group 112(1)-112(4) for each switch circuit 104(1)-104(4), respectively. Each control signal group 112(1)-112(4) may include multiple pulse-width modulated (PWM) signals causes the corresponding switch circuit 104(1)-104(4) to generate a dynamic HV control output 114(1)-114(4) to drive a corresponding load 120(1)-120(4), respectively. In the example of FIG. 1, each switch circuit 104(1)-104(4) drives a corresponding one of loads 120(1)-120(4); however, any one switch circuit 104 may drive multiple loads 120 without departing from the scope hereof. For example, multiple loads 120 may be grouped and driven from one switch circuit 104. In the example of FIG. 1, loads 120 represent HASEL actuators that are connected to provide cooperative actuation; however, HV waveform generator 100 may also drive independent loads without departing from the scope hereof.

Each switch circuit 104 also provides a feedback group 116 (e.g., at least one reference voltage signal that may be measured by controller 110) indicative of output of the switch circuit, and indicative of operation of load 120. In embodiments where loads 120 are HASEL actuators, a physical output of the actuator is a displacement and/or force that is a function of the voltage applied by HV waveform generator 100; the greater the applied voltage, the greater the displacement and/or force, and vice versa.

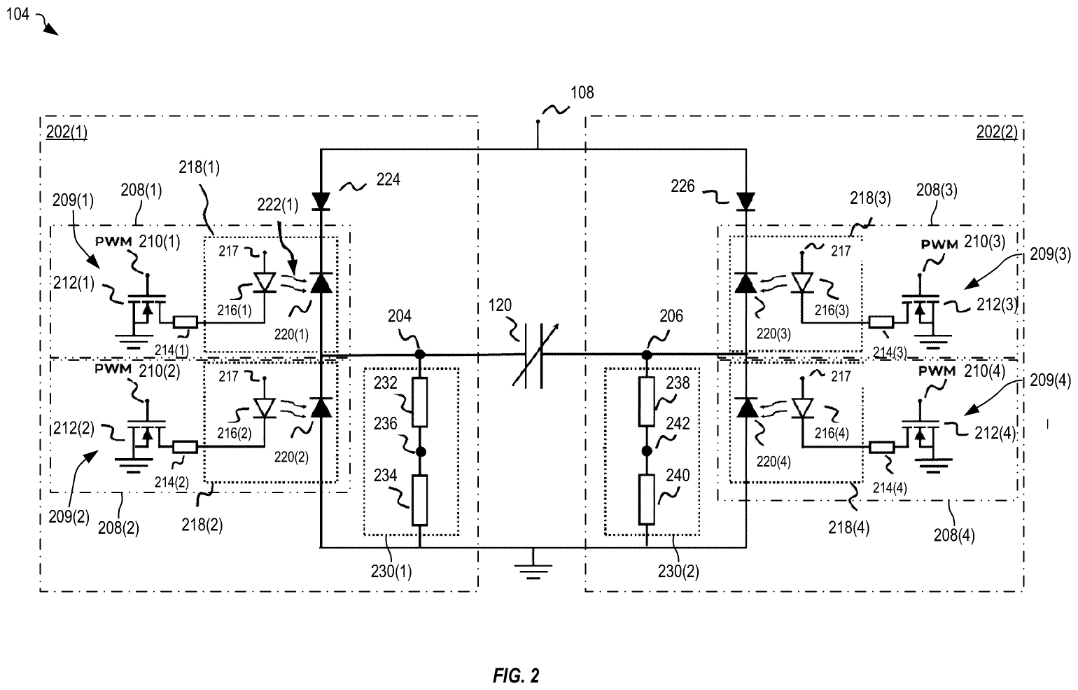

FIG. 2 is a circuit diagram illustrating example detail of switch circuit 104 of FIG. 1, in embodiments. Switch circuit 104 forms two channels 202(1) and 202(2) where channel 202(1) generates a first voltage output 204 of dynamic HV control output 114 and channel 202(2) generates a second voltage output 206 of dynamic HV control output 114. First voltage output 204 and second voltage output 206 cooperate to drive at least one load 120. However, first voltage output 204 and second voltage output 206 may cooperate to drive other devices without departing from the scope hereof. Channels 202(1) and 202(2) form an H-bridge configuration the allows polarity of dynamic HV control output 114 to be reversed.

Channel 202(1) includes a charge sub-circuit 208(1) and a discharge sub-circuit 208(2), and channel 202(1) includes a charge sub-circuit 208(1) and a discharge sub-circuit 208(2). Sub-circuits 208(1), 208(2), 208(3), and 208(4) are similar to one another. Charge sub-circuit 208(1) implements an HV switch between single HV rail 108 and first voltage output 204; discharge sub-circuit 208(2) implements an HV switch between first voltage output 204 and ground (e.g., a low potential); charge sub-circuit 208(3) implements an HV switch between single HV rail 108 and second voltage output 206; and discharge sub-circuit 208(4) implements an HV switch between second voltage output 206 and ground. For clarity of description, the term “ground” is used to refer to a low potential, which may or may not be grounded with respect to the Earth.

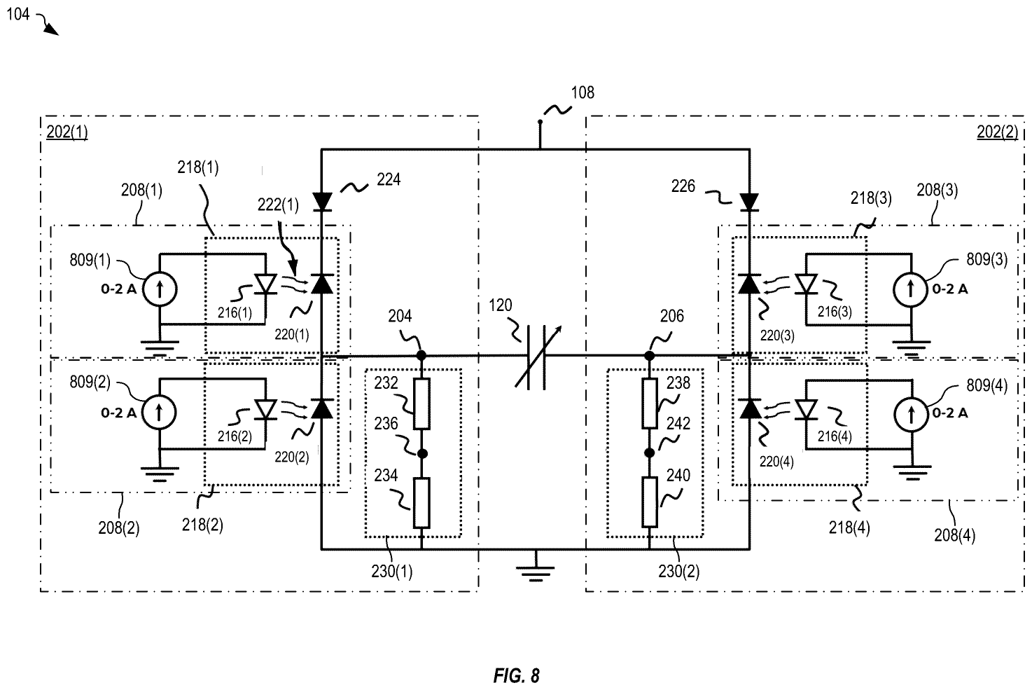

Sub-circuit 208(1) includes a first variable current source 209(1) formed with a PWM input 210(1) connected to a gate lead of an N-channel metal oxide silicon field effect transistor (MOSFET) 212(1) and a resistor 214(1), which is connected between a drain lead of N-channel MOSFET 212(1) and a cathode of an infrared (IR) light-emitting diode (LED) 216(1), and an anode of IR LED 216(1) connects to a suitable voltage source 217 (e.g., 5V, 3.3V, etc.). IR LED 216(1) is part of a charging optocoupler 218(1) that also includes an optical diode 220(1) that is controlled by IR light 222(1) generated by IR LED 216(1). When optical diode 220(1) is not exposed to IR light 222(1), it is in a nonconducting state; when optical diode 220(1) is exposed to IR light 222(1), transitions from the nonconducting state to a conducting state. Conductance of the IR LED 216(1) is directly related to the intensity of IR light 222(1), which is controlled by first variable current source 209(1). Although the embodiment of FIG. 2 shows first variable current source 209(1) implemented to receive a PWM signal, similar functionality may be achieved using an analog current source (e.g., variable current source 209), where the analog current source adjusts the intensity of IR LED 216(1), where intensity of IR light 222(1) is proportional to current drive, and thereby controls current through optical diode 220(1). For example, an analog current source may be a current controlled LED driver, that may be more suitable to a lower power design. FIG. 8 is a circuit diagram illustrating switch circuit 104 of FIG. 2 showing analog current sources 809(1)-809(4) representing variable current sources 209(1)-209(4).

As used herein, ‘charging’ terminology refers to charge sub-circuits 208(1), 208(3) and charging optocouplers 218(1), 218(3) since they have respective optical diodes 220(1), 220(3) with cathodes connected to single HV rail 108 (via one of HV diode 224 and 226) and anodes connected to a respective one of first voltage output 204 and second voltage output 206. Similarly, ‘discharging’ refers to discharge sub-circuits 208(2), 208(4) and discharging optocouplers 218(2), 218(4) since they have respective optical diodes 220(2), 220(4) with cathodes connected to a respective one of first voltage output 204, second voltage output 206, and anodes connected to ground (or low potential).

Sub-circuit 208(2) is connected similarly to sub-circuit 208(1) and includes a second variable current source 209(2) formed with a PWM input 210(2), an N-channel MOSFET 212(2), and a resistor 214(2), and an IR LED 216(2) that is part of a discharging optocoupler 218(2) that also includes an optical diode 220(2). Sub-circuit 208(3) is connected similarly to sub-circuit 208(1) and includes a third variable current source 209(3) formed with a PWM input 210(3), an N-channel MOSFET 212(3), and a resistor 214(3), and an IR LED 216(3) that is part of a discharging optocoupler 218(3) that also includes an optical diode 220(3). Sub-circuit 208(4) is connected similarly to sub-circuit 208(1) and includes a fourth variable current source 209(4) formed with a PWM input 210(4), an N-channel MOSFET 212(4), and a resistor 214(4), and an IR LED 216(4) that is part of a discharging optocoupler 218(4) that also includes an optical diode 220(4).

Within channel 202(1), an HV diode 224, optical diode 220(1), and optical diode 220(2) are connected in series between single HV rail 108 and ground, where an anode of HV diode 224 connects with single HV rail 108, an cathode of HV diode 224 connects with a cathode of optical diode 220(1), an anode of optical diode 220(1) connects with a cathode of optical diode 220(2) to form first voltage output 204, and an anode of optical diode 220(2) connects with ground. Within channel 202(2), an HV diode 226, optical diode 220(3), and optical diode 220(4) are connected in series between single HV rail 108 and ground, where an anode of HV diode 226 connects with single HV rail 108, an cathode of HV diode 226 connects with a cathode of optical diode 220(3), an anode of optical diode 220(3) connects with a cathode of optical diode 220(4) to form second voltage output 206, and an anode of optical diode 220(4) connects with ground. First voltage output 204 and second voltage output 206 may be less than or equal to a voltage of single HV rail 108. The difference between first voltage output 204 and second voltage output 206 is applied across load 120, which is connected to the output of switch circuit 104.

Channel 202(1) may also include a voltage monitor 230(1) having resistors 232 and 234 formed as a potential divider between first voltage output 204 and ground, where a first lead of resistor 232 connects to first voltage output 204, a second lead of resistor 232 connects with a first lead of resistors 234 to form reference voltage 236, and a second lead of resistor 234 connects to ground. Similarly, channel 202(2) may also include a voltage monitor 230(2) having resistors 238 and 240 formed as a potential divider between second voltage output 206 and ground, where a first lead of resistor 238 connects to second voltage output 206, a second lead of resistor 238 connects with a first lead of resistors 240 to form reference voltage 242, and a second lead of resistor 240 connects to ground. Resistors 232 and 238 may have values on the order of 1 Gohm, and resistors 234 and 240 may have values on the order of 300 kohm, whereby actual values of resistors 232, 234, 238, and 240 are determined based on a voltage of single HV rail 108 such that reference voltages 236 and 242 have a maximum voltage of 3.3V, which is a maximum input voltage of a measurement device (analog-to-digital converter) of controller 110.

In the embodiments of FIGS. 1 and 2, each control signal group 112 includes four different PWM signals that are input to switch 104 as PWM inputs 210(1), 210(2), 210(3), and 210(4). A duty cycle (e.g., ratio of on-time to off-time) of each PWM signal dictates conductance of the optical diodes that supply current from single HV rail 108 to load 120 (or from load 120 to ground). A PWM signal with a high duty cycle causes the corresponding optical diode 220 to conduct a high current. A PWM signal with a low duty cycle causes the corresponding optical diode 220 to conduct a low current. Where there is no PWM signal (e.g., the PWM signal is at steady ground), the corresponding optical diode 220 conducts no current, and correspond the sub-circuit 208(1) being off. Accordingly, the duty cycle and duration of the PWM signal at PWM input 210(1) (and PWM input 210(3)) dictates the amount of charge supplied to (or charge drained from) first voltage output 204 and/or second voltage output 206. Particularly, the variable duty cycle controls the amount of current supplied to IR LED 216(1), which dictates its intensity, which controls the conductance of optical diode 220(1). As noted above, in certain embodiments, analog current sources may be controlled by controller 110 to determine current through IR LEDs 216, and thereby control conductance of optical diodes 220.

Accordingly, to control load 120, controller 110 generates each PWM signal of control signal group 112 to set the amount of current passed by the corresponding optocoupler 218 of switch circuit 104. Since each optocoupler 218 is controlled independently, controller 110 may control first voltage output 204 and second voltage output 206 independently. For example, to charge load 120, controller 110 generates the PWM signals to control charging optocoupler 218(1) to allow current to flow from single HV rail 108 via optical diode 220(1) to first voltage output 204 and controls discharging optocoupler 218(4) to allow current to flow from second voltage output 206 via optical diode 220(4) to ground. In another example, to charge load 120 with reversed polarity, controller 110 generates the PWM signals to control charging optocoupler 218(3) to allow current to flow from single HV rail 108 via optical diode 220(3) to second voltage output 206 and controls discharging optocoupler 218(2) to allow current to flow from first voltage output 204 via optical diode 220(2) to ground. To discharge load 120, charging optocouplers 218(1) and 218(3) are turned off (e.g., high impedance) and discharging optocouplers 218(2) and 218(4) are turned on (e.g., high conductance).

Where this current is supplied for a sufficient amount of time, load 120 charges up towards the voltage of single HV rail 108 (with the caveat that this applied current needs to be greater than the leakage current of voltage monitor 230(1) and leakage current of load 120 in order for the actuator to charge load 120). Similarly, controller 110 generates the PWM signals to control discharging optocouplers 218(1) and 218(3) to allow current to flow from load 120 to ground. Controller 110 may also control optocouplers 218 to isolate load 120 from both single HV rail 108 and ground.

For capacitive loads (e.g., load 120), a duty cycle of the PWM signal controls the high voltage current through the corresponding optical diode 220, which dictates the rate at which the capacitive load charges, and the duration of the PWM signal controls the output voltage. Thus, the duty cycle and duration of the PWM signal, and the capacitive load connected between first voltage output 204 and second voltage output 206 affects operation of switch circuit 104. A further effect on performance of each optocoupler 218 is a distance between IR LED 216 and optical diode 220, which may vary in manufacture of each optocoupler 218.

In certain embodiments, controller 110 may include an algorithm that processes these variables to generate the appropriate PWM signals of the appropriate duration to achieve the desired functionality of load 120. However, given unpredicted variation in performance of optocouplers 218 and a potentially unknown capacitive load of load 120, a direct formula approach may be less effective. An alternative approach is to test each switch circuit 104 to develop calibration curves (e.g., in the form of tables or functions) of current through optocoupler vs duty cycle of PWM signal. These calibration curves define a relationship between a duty cycle of the PWM signal and conductance of optical diode 220. For example, the calibration curves may be determined using both low and high reverse voltages, since the conductance of optical diode 220 is primarily a function of an intensity of IR light 222, which is analogous to the PWM duty cycle or variable current source 209 (e.g., current through IR LED 216). These calibration curves may be stored within memory of controller 110. Controller 110 may then use these calibration curves to determine an appropriate variable current source 209 (e.g., by generating PWM signal) for a desired current and effect on load 120.

The calibration curves define a maximum steady state high voltage current through optical diode 220 as a function of current through IR LED 216. Where load 120 is capacitive, current drawn is a function of the dynamic load and reduces as the capacitive load charges; however, the initial peak current is defined by the calibration curves. Where load 120 is resistive, current through optical diode 220 is defined by the calibration curve.

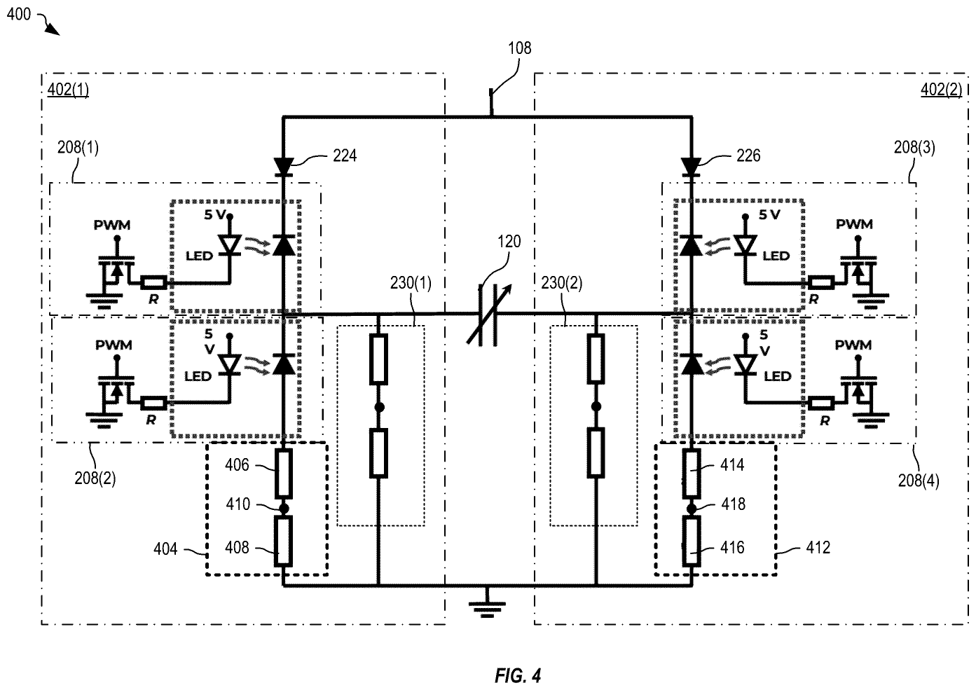

As shown in the embodiment of FIG. 4, and described below, current may be actively monitored to determine a dynamic behavior of load 120. Further, as described below, voltage at first voltage output 204 and second voltage output 206 may be monitored to determine a dynamic state of load 120.

By monitoring voltage (e.g., using voltage monitors 230(1) and 230(2)) and current monitors (e.g., derived from voltage monitors 230(1) and 230(2)), controller 110 determines power supplied to load 120, and controller 110 may thereby infer behavior of load 120 (e.g., where load 120 is a HASEL actuator). For example, controller 110 may receive and digitize reference voltage 236 and reference voltage 242 to capture feedback of both first voltage output 204 and second voltage output 206, and operation of load 120. Particularly, since polarity of first voltage output 204 and second voltage output 206 may be reversed through operation of PWM inputs 210, switch circuit 104 may be used to both charge and discharge load 120. Advantageously, through use of voltage monitors 230(1) and 230(2) and derived current, controller 110 may control switch circuit 104 to generate almost any arbitrary voltage waveform for load 120. Although switch circuit 104 is shown with optocouplers 218 in this embodiment, for certain selected voltages of single HV rail 108, other embodiments may replace optocouplers 218 with other components, such as MOSFETs, insulated-gate bipolar transistors (IGBTs), and other semiconductor-based switches. For example, where single HV rail 108 is at or below 4/5 kV, P-channel enhancement mode MOSFETs may be used instead of optocoupler 218(1) and 218(3), and N-channel enhancement mode MOSFETS or other high voltage transistors may be used instead of optocouplers 218(2) and 218(4). Similarly, where single HV rail 108 is limited to a few thousand volts, IGBTs may be used in place of optocouplers 218, since IGBT technology is suitable for operation at hundreds up to a few thousand volts.

Controller 110 may derive both charging and discharging currents (e.g., currents through optical diodes 220(2) and 220(4)) as follows. Conductance of each optical diode 220(1)-220(4) is directly related to a duty cycle of the PWM signals applied to PWM input 210(1)-210(4), and thus may be calculated by controller 110 since the duty cycle of each PWM signal is set by controller 110.

Controller 110 may measure (e.g., using an analog-to-digital converter) reference voltage 236 and reference voltage 242 to derive voltages at first voltage output 204 and second voltage output 206. Since current through each optical diode 220 is directly related to the corresponding PWM signal, controller 110 may use calibration curves to directly determine a peak current to or from load 120. Accordingly, controller 110 may use the measured voltage and determined current to calculate power consumption of load 120. Advantageously, controller 110 may monitor the voltage and current of load 120 to predict failure modes, signify faults or short circuits, and implement safety features. Controller 110 uses the architecture of switch circuit 104 to actively limit output current by controlling the duty cycle of PWM signals, which is a low voltage signal. Many HV safety procedures impose strict current limitations. Accordingly, controller 110 modifies the generated PWM signals to control peak output current to meet these regulations without changing hardware. Further, where controller 110 determines that a measured voltage (e.g., using voltage monitors 230) indicates a short circuit (e.g., zero volts between first voltage output 204 and second voltage output 206), when the generated PWM signals correspond to a high voltage, controller 110 implements a safety procedure that immediately turns off charging optocouplers 218(1) and 218(3) to disconnect and prevent current flow from single HV rail 108 to first voltage output 204 and second voltage output 206. Additionally, controller 110 may generate PWM signals to turn on discharge optocouplers 218(2) and 218(4) to drain any remaining charge at first voltage output 204 and second voltage output 206 (e.g., within load 120).

By measuring and driving voltage and current of load 120, controller 110 may generate control signal group 112 to cause switch circuit 104 to match power consumption of load 120. That is, controller 110 may generate control signal group 112 to cause switch circuit 104 to match an inherent ‘catch’ or ‘latch’ state, where load 120 represents a HASEL actuator for example, and thereby consume little power to hold the actuator in an actuated state. For example, controller 110 may determine, from voltage monitors 230, when load 120 is close to, or at, a desired voltage threshold (e.g., within 100 V of the rail voltage), and generates control signal group 112 to cause optical diodes 220 to transition to a low-power consumption state (i.e. low duty cycle or off completely). This drastically conserves power at lower actuation frequencies and reduces thermal signature of sub-circuits 208.

In certain embodiments, controller 110 is a proportional—integral—derivative controller (PID) controller implementing a control loop mechanism that uses feedback from voltage monitors 230 to continuously modulate first voltage output 204 and second voltage output 206 by varying PWM signals of the corresponding control signal group 112. That is, controller 110 may vary PWM signals of each control signal group 112 based on reference voltages within the corresponding feedback group 116. Accordingly, controller 110 drives load 120 by control of first voltage output 204 and second voltage output 206 irrespective of the state or function of load 120. Advantageously, controller 110 thereby reduces load-dependence of HV waveform generator 100. For example, HV waveform generator 100, through use of feedback group 116 by controller 110, achieves a desired response regardless of the capacitive load at first voltage output 204 and second voltage output 206.

In one example of operation, HV source 106 generates single HV rail 108 at a constant DC output of a maximum desired voltage (e.g., 6 kV-8 kV for HASEL actuators, but could be anything from 0-15 kV). HV diodes 224 and 226 prevent voltage or current surges at first voltage output 204 and second voltage output 206 from damaging HV source 106. This is relevant for a generator mode of electrostatic transducers, for example. Also, HV diodes 224 and 226 reduce cross talk between switch circuits 104 when HV source 106 (e.g., single HV rail 108) drives multiple outputs. Optical diodes 220 are used in reverse bias, since any of them may see reverse voltages as high as single HV rail 108. Thus, when all optocouplers 218 are off, then optical diodes 220(1) and 220(3) see the rail voltage. This is normal, they can withstand this reverse voltage indefinitely. When optocoupler 218(1) is turned on, then optical diode 220(2) sees up to the rail voltage. Similarly, when optocoupler 218(3) is on, then optical diode 220(4) sees up to the rail voltage.

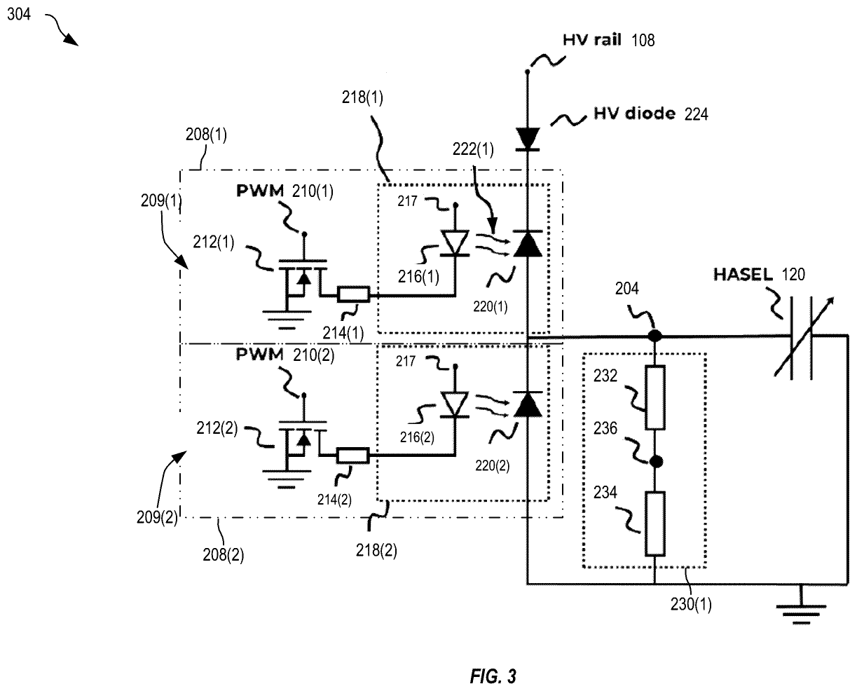

As previously noted, the use of four HV switches (e.g., sub-circuits 208) in an H-bridge configuration allows the polarity of the applied voltage between first voltage output 204 and second voltage output 206 to be reversed. Particularly, the H-bridge configuration uses two charge sub-circuits 208(1) and 208(3) and two discharge sub-circuits 208(2) and 208(4). However, where reverse polarity of first voltage output 204 and second voltage output 206 is not required, second channel 202(2) may be omitted from switch circuit 104, as shown in FIG. 3.

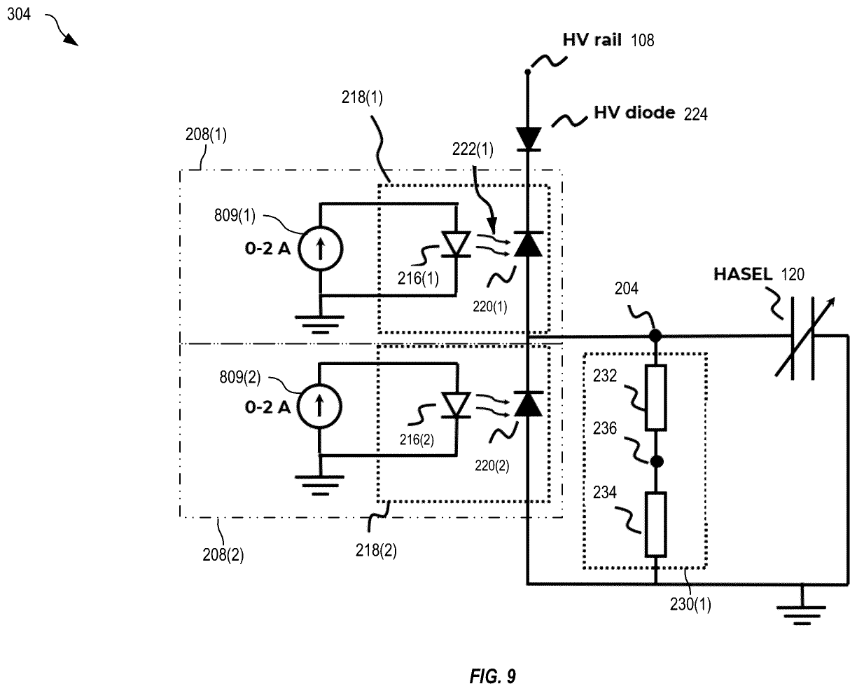

FIG. 3 shows one example switch circuit 304 with the second channel omitted, in embodiments. Particularly, switch circuit 304 is used where polarity reversal of first voltage output 204 and second voltage output 206 is not required. In this embodiment, load 120 connects between first voltage output 204 and ground, as shown. FIG. 9 is a circuit diagram illustrating switch circuit 304 of FIG. 3 showing analog current sources 809(1) and 809(2) representing variable current sources 209(1) and 209(2).

### Example Multi-Frequency Operation

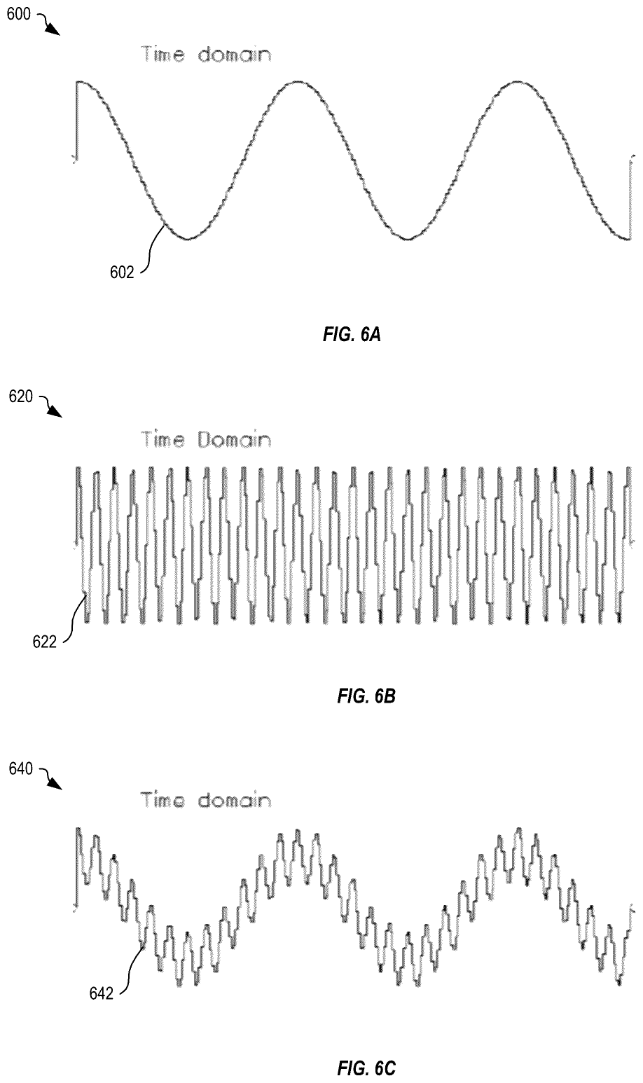

In one example of operation, controller 110 generates PWM signals of control signal group 112(1) to cause channel 202(1) and channel 202(2) to pulse at different frequencies, such as channel 202(1) pulsing at a low frequency (e.g., 1 Hz, or 0.001 Hz or greater) and channel 202(2) pulsing at a high frequency (e.g., 100 Hz, typically 1 kHz or less for HASEL actuators, but switch circuit 104 may operate up to 500 KHz), which causes first voltage output 204 and second voltage output 206 to have a superimposed waveform that is applied to load 120 (e.g., see FIGS. 6A, 6B, and 6C). Particularly, where load 120 represents a HASEL actuator, this may control the HASEL actuator to have a low frequency macroscopic motion combined with a high frequency vibration, as may be useful when the HASEL actuator applies haptic, compression therapies, etc. For example, the superimposed frequencies create a motion pattern in the HASEL actuator that combines macroscopic motion (e.g., low frequency actuation that's on the mm or cm-scale) with microscopic vibrations (e.g., high frequency vibrations that're on the micrometer scale). Accordingly, the HASEL actuator may impart a continuous low intensity vibration at the same time as providing the larger scale macroscopic motion. These types of motion patterns are useful for haptic stimulator or sensation based applications that require both a vibration and more discernable macroscale force or motion. There is also evidence that these types of motion are beneficial for compression therapies as they stimulate blood flow through vibration while also providing a more pin-pointed pressure (macroscale motion).

The superimposed waveforms are possible with a H-bridge topology, as shown in FIG. 2. To achieve this functionality for example, the first channel is pulsed at 1 Hz (optical diode 220(1) on for 0.5 second while optical diode 220(2) is off and then vice versa), while the second channel is pulsed at 200 Hz (optical diode 220(3) on for 0.005 s while optical diode 220(4) is off and then vice versa). In the single channel embodiment of FIG. 3, PWM signals on inputs 210(1) and 210(2) may be generated to include multiple frequencies, thereby causing first voltage output 204 to implement macroscopic motion and microscopic vibrations.

Advantageously, the use of HV waveform generator 100 avoids a need for a highly dynamic HV amplifier, which typically increases both cost and complexity of the driving electronics. Further, HV waveform generator 100 is easy to scale to many switch circuits 104 that may each be independently controlled by controller 110 to vary the properties of the superimposed waveform and thus the response of the corresponding load 120.

A further advantage is that controller 110 may control charge sub-circuit 208(1) and discharge sub-circuit 208(2) to activate simultaneously at different conductance levels to cause optical diodes 220(1) and 220(2) to function as a voltage divider that dictates a steady state voltage of load 120. Further, controller 110 may operates as a PID controller to regulate the voltages at load 120 to be at or below a voltage of single HV rail 108. Advantageously, controller 110 provides voltage regulation at first voltage output 204 and second voltage output 206 (e.g., the voltage across load 120) that is less load dependent. Particularly, HV waveform generator 100 allows load 120 to be charged or discharged to a voltage below that of single HV rail 108 and held in that state. Accordingly, a user of HV waveform generator 100 may define customized voltage profiles at first voltage output 204 and second voltage output 206 that are implemented by controller 110.

Prior-art amplifiers supply current to charge a capacitive load at an output but do not measure voltage across the load, and therefore cannot determine an output state. Capacitive loads always charge to the rail voltage while current is supplied, and thus the voltage across the load changes over time. Switch circuit 104 advantageously includes voltage monitors 230 that provide voltage feedback for both first voltage output 204 and second voltage output 206, since both are independently controlled. Accordingly, where it is desired to charge load 120 to a fraction of the voltage at single HV rail 108, controller 110 disconnects (e.g., controls PWM signals to transition optical diodes 220 to a non-conductive state) first voltage output 204 and second voltage output 206 from single HV rail 108 when the desired output voltage is reached. When controller 110 detects that the output voltage at first voltage output 204 and second voltage output 206 drops below the desired voltage (e.g., due to leakage currents and/or a dynamic load at load 120), controller 110 generates PWM signals to supply more charges to recover the voltage at first voltage output 204 and second voltage output 206. Similarly, when controller 110 detects the voltage at first voltage output 204 and second voltage output 206 exceeding the desired voltage, (e.g., due to a dynamic load at load 120), controller 110 controls PWM signals to discharge current from load 120. Voltage monitors 230 provide feedback to controller 110 (e.g., a closed loop) to allow controller 110 to provide a precise control of more precise output voltage profiles.

FIG. 4 is a circuit diagram illustrating one example H-bridge configuration switch circuit 400 with a current monitor in each channel, in embodiments. Switch circuit 400 is similar to switch circuit 104 of FIG. 2 and includes two channels 402(1) and 402(2) with sub-circuits 208(1)-208(4), HV diode 224 and 226, and voltage monitors 230(1) and 230(2), which are not further labeled for clarity of illustration. Channel 402(1) further includes a current monitor 404 positioned between the anode of optical diode 220(2) of discharge sub-circuit 208(2) and ground as shown. Current monitor 404 includes two resistors 406 and 408 connected in series as a potential divider to provide a voltage sense signal 410 that may be fed back to controller 110 to provide an indication of current through optical diode 220(2). Similarly, 402(2) further includes a current monitor 412 positioned between the anode of optical diode 220(4) of discharge sub-circuit 208(4) and ground as shown. Current monitor 412 includes two resistors 414 and 416 connected in series as a potential divider to provide a central voltage reference 418 that may be fed back to controller 110 to provide an indication of current through optical diode 220(4). In certain embodiments, where resistors 408/416 are selected such that voltage sense signals 410/218 remain within a sensing range (e.g., 5V or 3.3V, etc.) during transient charging and discharging of load 120, resistors 406/414 may be omitted.

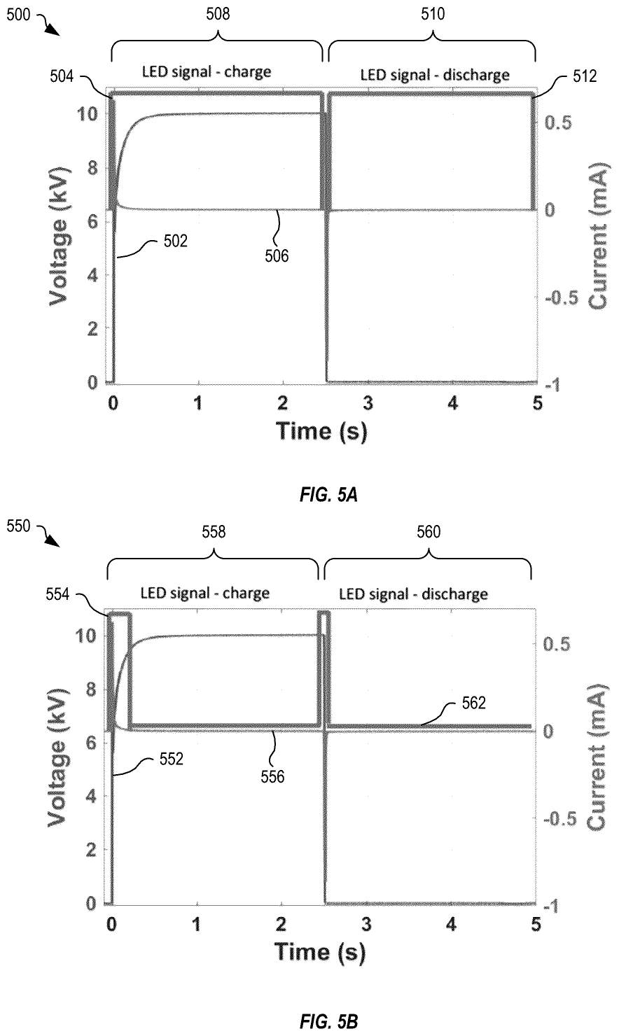

FIG. 5A is a graph 500 illustrating example operation of HV waveform generator 100 of FIG. 1 for conventional operation of load 120. FIG. 5B is a graph 550 illustrating example operation of HV waveform generator 100 of FIG. 1 for improved operation of load 120. FIGS. 5A and 5B are best viewed together with the following description.

Graph 500 shows a voltage waveform 502 of first voltage output 204, an LED signal activity waveform 504 that represents current through IR LED 216(1) to activate optical diode 220(1), a current waveform 506 indicative of current through optical diode 220(1), and an LED signal activity waveform 512 that represents current through IR LED 216(2) to activate optical diode 220(2), that are time aligned over a period of five seconds. LED signal activity waveform 504 shows that IR LED 216(1) is continuously active during a charge period 508 such that optical diode 220(1) remains conductive (e.g., connecting first voltage output 204 to single HV rail 108). During charge period 508, voltage waveform 502 increases from zero to 10 kV (e.g., a voltage of single HV rail 108), and current waveform 506 indicates that current initially peaks as load 120 begins to charge and then reduces towards zero as load 120 becomes charged. However, LED signal activity waveform 504 does not return to inactive until charge period 508 ends. Accordingly, IR LED 216(1) is active for the duration of charge period 508. Similarly, during discharge period 510, LED signal activity waveform 512 shows that IR LED 216(2) is continuously active during discharge period 510 such that optical diode 220(2) remains conductive (e.g., connecting first voltage output 204 to ground). During discharge period 510, voltage waveform 502 reduces to zero from its charged state (e.g., 10 kV), and current waveform 506 indicates that current initially peaks negatively as load 120 begins to discharge and then reduces towards zero as load 120 becomes discharged. However, LED signal activity waveform 512 does not return to inactive until discharge period 510 ends.

Particularly, LED signal activity waveform 504 and LED signal activity waveform 512 show that IR LEDs 216(1) and 216(2) remain active even when voltage change and current flow is minimal.

Graph 550 shows a voltage waveform 552 of first voltage output 204, an LED signal activity waveform 554 that represents current through IR LED 216(1) to activate optical diode 220(1), a current waveform 556 indicative of current through optical diode 220(1), and an LED signal activity waveform 562 that represents current through IR LED 216(2) to activate optical diode 220(2), that are time aligned over a period of five seconds. LED signal activity waveform 554 shows that IR LED 216(1) is active only during an initial portion of charge period 558 (and not the entire charge period 558), transitioning to inactive as voltage waveform 552 reaches 10 kV and current waveform 556 reduces towards zero. Accordingly, once controller 110 determines that load 120 is charged, control signal group 112 is modified such that PWM signals deactivate IR LEDs 216(1) and 216(2), causing optical diode 220(1) and 220(2) to transition to high impendence.

Similarly, during a discharge period 560, LED signal activity waveform 562 indicates that IR LED 216(2) is active only for a short portion of discharge period 560 (e.g., not all of discharge period 560), transitioning to inactive as voltage waveform 552 reaches zero (e.g., ground) and current waveform 556 reduces towards zero. Accordingly, once controller 110 determines that load 120 is discharged, control signal group 112 is modified such that PWM signals deactivate IR LEDs 216(1) and 216(2), causing optical diode 220(1) and 220(2) to transition to high impendence.

Advantageously, where load 120 is a HASEL actuator, controller 110 takes advantage of a catch state of the HASEL actuator and only activates charge sub-circuit 208(1) and discharge sub-circuit 208(2) to transition load 120 between states. For electrostatic devices (e.g., capacitive loads such as the HASEL actuator and capacitors) the catch state is a condition where once the electrostatic device is charged, it requires very little power to hold that charge. In the case where load 120 is a HASEL actuator, holding the charge means holding an actuated state. Generally, a HASEL actuator consumes only milliwatts of power to hold an actuated state indefinitely. Importantly, most prior art power supply solutions implement a passive resistor to discharge power from the electrostatic device once power is no longer supplied. While this prior art approach is simple, it completely negates the advantage of low power consumption of the electrostatic device once charged, since power is always required to hold the actuated state because of the discharge through the passive resistor. Accordingly, HV waveform generator 100 provides a significant advantage of the prior art because optocouplers 218 may be controlled to isolate first voltage output 204 and second voltage output 206 from both single HV rail 108 and ground.

Advantageously, through use of voltage monitors 230 (and optional current monitors 404 and 412, where continuous activation of IR LEDs 216(1) and/or 216(2) cause overheating, controller 110 is able to deactivate IR LED 216(1) and/or 216(2) to avoid overheating. Particularly, controller 110 takes advantage of the individual control of optical diodes 220(1)-220(4) to transition them to low conductance (e.g., a low duty cycle of the corresponding PWM signal). This conserves power and prevents overheating, particularly at low frequency operations.

FIG. 6A is a graph 600 showing a low frequency signal 602. FIG. 6B is a graph 620 showing a high frequency signal 622. FIG. 6C is a graph 640 showing an example output 642 of HV waveform generator 100 that combines low frequency signal 602 and high frequency signal 622.

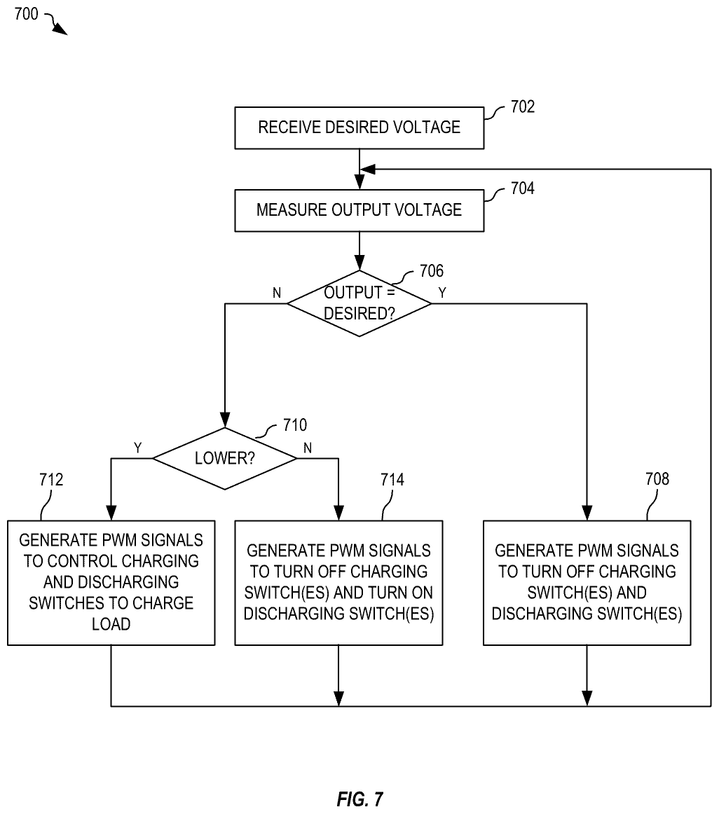

FIG. 7 is a flowchart illustrating one example method 700 for HV waveform generation, in embodiments. Method 700 is implemented by controller 110 of HV waveform generator 100 of FIG. 1, for each switch circuit 104 of HV waveform generator 100, for example. In the H-bridge configuration of FIG. 2, channels 202 of each switch circuit 104 are controlled collectively to cooperatively provide control of load 120 via first voltage output 204 and second voltage output 206 as described above.

In block 702, method 700 receives a desired voltage. In one example of block 702, controller 110 receives an input indicating that load 120 to be charged to 6 kV. In another example of block 702, the desired voltage is determined based on time (e.g., by a function or algorithm running within controller 110). For example, where the function or algorithm generates a sine wave at a given frequency and amplitude defined by user input, controller 110 determines the desired output voltage over time. Block 702 may receive or determine a desired voltage at any time (e.g., asynchronous to operation of method 700) whereby any change in the desired voltage is processed in blocks 706 and 710.

In block 704, method 700 measures an output voltage. In one example of block 704, controller 110 captures reference voltages 236 and 242 from voltage monitors 230(1) and 230(2). Block 706 is a decision. If, in block 706, method 700 determines that the output voltage matches the desired voltage, method 700 continues with block 708; otherwise, method 700 continues with block 710. In block 708, method 700 generates PWM signals to turn off charging switch(es) and discharging switch(es). In one example of block 708, controller 110 generates PWM signals of control signal group 112(1) to transition optical diodes 220(1), 220(2), 220(3), and 220(4) to low conductance (e.g., high-impedance) to disconnect first voltage output 204 and second voltage output 206 from both single HV rail 108 and ground. Method 700 then returns to block 704.

Block 710 is a decision. If, in block 710, method 700 determines that the desired voltage is lower than the output voltage, method 700 continues with block 712; otherwise, method 700 continues with block 714. In block 712, method 700 generates PWM signals to control charging switches and discharging switches to charge the load. In one example of block 712, controller 110 generates PWM signals of control signal group 112(1) to transition optical diodes 220(1) and 220(4) to a conducting state and to transition optical diodes 220(2) and 220(3) to a nonconducting state. In another example of block 712, controller 110 generates PWM signals of control signal group 112(1) to transition optical diodes 220(2) and 220(3) to a conducting state and to transition optical diodes 220(1) and 220(4) to a nonconducting state. Method then continues with block 704.

In block 714, method 700 generates PWM signals to turn off charging switch(es) and turn on discharging switch(es). In one example of block 714, controller 110 generates PWM signals of control signal group 112(1) to transition optical diodes 220(1) and 220(3) to a nonconducting state and to transition optical diodes 220(2) and 220(4) to a conducting state. Method then continues with block 704.

### Applications

HV waveform generator 100 is particularly suited for the following applications: powering electrostatic systems, driving HASEL actuators, driving dielectric elastomer actuators, driving electro-adhesive devices, driving electrostatic motors and pumps, driving electro-pneumatic actuators, driving micro-electromechanical (MEMS) systems, driving electrostatic cantilevers, switches, micro-actuators, micro-fluidic pumps, driving electrostatic sprayers for coating processes such as for disinfectants, aerosols, paints, etc., driving Automated External Defibrillators (AEDs), driving mass spectroscopy equipment, Cytometry, Electrophoresis, Electrosurgery, Dielectric testing, Lasers, LIDAR systems, Electrical separation, Electrostatic air filters, and Semiconductor processing.

Changes may be made in the above methods and systems without departing from the scope hereof. It should thus be noted that the matter contained in the above description or shown in the accompanying drawings should be interpreted as illustrative and not in a limiting sense. The following claims are intended to cover all generic and specific features described herein, as well as all statements of the scope of the present method and system, which, as a matter of language, might be said to fall therebetween.

What is claimed is:

1. A high-voltage (HV) waveform generator, comprising:
an HV source configured to generate a single HV rail at a predefined voltage with respect to a low potential;
at least one switch circuit having:
a first charge sub-circuit implementing a first switch to electrically couple the single HV rail and a first voltage output;
a first discharge sub-circuit implementing a second switch to electrically couple the first voltage output and the low potential;
a second charge sub-circuit implementing a third switch to electrically couple the single HV rail and a second voltage output; and
a second discharge sub-circuit implementing a fourth switch to electrically couple the second voltage output and the low potential; and
a controller having at least one digital processor and memory storing machine-readable instructions that, when executed by the digital processor, cause the digital processor to generate a first variable current source input to the first charge sub-circuit to control the first switch, a second variable current source input to the first discharge sub-circuit to control the second switch, a third variable current source input to the second charge sub-circuit to control the third switch, and a fourth variable current source input to the second discharge sub-circuit to control the fourth switch.

2. The HV waveform generator of claim 1, a polarity of the first voltage output and the second voltage output being reversable.

3. The HV waveform generator of claim 1, each of the first, second, third, and fourth switches comprising an optocoupler.

4. The HV waveform generator of claim 1, each of the first, second, third, and fourth switches having variable conductance based on the first, second, third, and fourth variable current sources.

5. The HV waveform generator of claim 1, at least one of the first, second, third and fourth variable current sources being controlled by a duty cycle of a pulse-width modulated signal.

6. The HV waveform generator of claim 1, the first switch and the second switch operating as a potential divider to control a voltage at the first voltage output.

7. The HV waveform generator of claim 1, the third switch and the fourth switch operating as a potential divider to control a voltage at the second voltage output.

8. The HV waveform generator of claim 1, the first, second, third, and fourth switches each comprising an optical diode.

9. The HV waveform generator of claim 1, the at least one switch circuit further comprising:
a first voltage monitor connected between the first voltage output and the low potential and configured to generate a first reference voltage indicative of a first voltage at the first voltage output;
a second voltage monitor connected between the second voltage output and the low potential and configured to generate a second reference voltage indicative of a second voltage at the second voltage output; and
the memory further comprising machine-readable instructions that, when executed by the digital processor, cause the digital processor to generate the first variable current source, the second variable current source, the third variable current source, and the fourth variable current source based on at least one of the first reference voltage and the second reference voltage.

10. The HV waveform generator of claim 9, the memory further comprising machine-readable instructions that, when executed by the digital processor, cause the digital processor to transition the first, second, third, and fourth switches to a high-impedance state when a voltage between the first voltage output and the second voltage output is at a desired voltage.

11. The HV waveform generator of claim 10, wherein the desired voltage indicates a latch state of an electrostatic actuator electrically coupled between the first voltage output and the second voltage output.

12. The HV waveform generator of claim 10, wherein the first, second, third, and fourth switches being in the high-impedance state reduces power consumption of the HV waveform generator.

13. The HV waveform generator of claim 9, the memory further comprising machine-readable instructions that, when executed by the digital processor, cause the digital processor to transition the first, second, third, and fourth switches to a high-impedance state when a voltage between the first voltage output and the second voltage output is indicative of a short circuit between the first voltage output and the second voltage output.

14. The HV waveform generator of claim 9, the memory further comprising machine-readable instructions that, when executed by the digital processor, cause the digital processor to generate the first variable current source and the second variable current source to generate a first voltage waveform of a first frequency at the first voltage output, and to generate the third variable current source and the fourth variable current source to generate a second voltage waveform of a second frequency at the second voltage output, wherein the first and second frequencies combine at an electrostatic actuator electrically coupled between the first voltage output and the second voltage output to impart a continuous low intensity vibration simultaneously as providing a larger scale motion.

15. A high-voltage (HV) waveform generator, comprising:
an HV source configured to generate a single HV rail at a predefined voltage with respect to a low potential;
at least one switch circuit having:
a charge sub-circuit implementing a first switch to electrically couple the single HV rail and a voltage output; and
a discharge sub-circuit implementing a second switch to electrically couple the voltage output and the low potential; and
a controller having at least one digital processor and memory storing machine-readable instructions that, when executed by the digital processor, cause the digital processor to generate a first variable current source input to the charge sub-circuit to control the first switch, and a second variable current source input to the discharge sub-circuit to control the second switch.

16. The HV waveform generator of claim 15, each of the first and second switches comprising an optocoupler.

17. The HV waveform generator of claim 15, each of the first and second switches having variable conductance based on the first and second variable current sources.

18. The HV waveform generator of claim 15, at least one of the first and second variable current sources being controlled by a duty cycle of a pulse-width modulated signal.

19. The HV waveform generator of claim 15, the first switch and the second switch operating as a potential divider to control a voltage at the voltage output with respect to low potential.

20. The HV waveform generator of claim 15, the first and second switches each comprising an optical diode.

21. The HV waveform generator of claim 15, the at least one switch circuit further comprising:
a voltage monitor connected between the voltage output and the low potential and configured to generate a reference voltage indicative of a voltage at the voltage output; and
the memory further comprising machine-readable instructions that, when executed by the digital processor, cause the digital processor to generate the first variable current source and the second variable current source based on the first reference voltage.

22. The HV waveform generator of claim 21, the memory further comprising machine-readable instructions that, when executed by the digital processor, cause the digital processor to transition the first and second switches to a high-impedance state when a voltage between the first voltage output and low potential is at a desired voltage to reduce power consumption of the HV waveform generator.
